(19) United States
(12) Patent Application Publication
(10) Pub. No.: US 2012/0123711 A1
(43) Pub. Date: May 17, 2012

(54) System and Method for Measuring Power Usage

(75) Inventors: Andrew T. Fausak, Foster City, CA (US); Songly Mu, Salida, CA (US); Darren Ybarra, Boise, ID (US)

(73) Assignee: Asoka USA Corporation, Santa Clara, CA (US)

(21) Appl. No.: 12/919,680

(22) PCT Filed: Feb. 27, 2009
(86) PCT No.: PCT/US09/35573

§ 371 Date: Nov. 22, 2010

Related U.S. Application Data
(60) Provisional application No. 61/032,037, filed on Feb. 27, 2008.
(60) Provisional application No. 61/032,042, filed on Feb. 27, 2008.

(51) Int. Cl. G06F 19/00; G01R 21/00

(52) U.S. Cl. 702/62

(57) ABSTRACT

A system and method for monitoring energy usage through a power line network is disclosed. According to an embodiment, the present system for monitoring power usage comprises a power line having one or more phases and metering device. The metering device comprises an A/D converter configured to receive an electrical signal and convert the electrical signal to a digital signal, a processor configured to calculate power usage information using the digital signal, and a network interface module configured to transmit the power usage information to a server via the power line network.

### FIELD

The present disclosure relates generally to energy usage and power line networking techniques, and more particularly to a method and system for measuring power usage by coupling a power meter to a power line network.

### BACKGROUND

As the demand for energy increases, costs for energy have increased dramatically. The majority of energy is generated from conventional resources such as fossil fuels, hydroelectric plants, and nuclear sources. Energy is being rapidly consumed and is on the verge of exhaustion as the demand for energy grows at an unparalleled pace. Accordingly, with ever increasing world population and energy demand, energy will become scarce and very expensive.

Average customers do not have an easy way to monitor and manage their power usage. They rely upon a conventional power meter provided by their utility company to monitor their power consumption. Power meters are typically disposed at a hard-to-reach place outside of their residence. Most customers do not even have a willingness to inspect their power meters and confirm the energy bill that they are paying for. Customers may want to inspect their bill to confirm whether they are billed correctly and fairly. Some smart customers may want to monitor their monthly usage and compare it with their previous records. The reading afforded by the conventional power meters does not provide such detailed information as when and how the electricity was used, and what appliances consumed how much electricity. To make it worse, most customers simply cannot even track power usage in a meaningful and effective manner.

Lack of power management causes unnecessary energy waste and the increase in energy cost. With recent advancements in technology, more and more homes and buildings are equipped with energy saving appliances and materials. From the above, it is seen that techniques for improving usage of energy in a home or building is highly desirable.

### SUMMARY

A system and method for monitoring energy usage through a power line network is disclosed. According to an embodiment, the present system for monitoring power usage comprises a power line having one or more phases and metering device. The metering device comprises an A/D converter configured to receive an electrical signal and convert the electrical signal to a digital signal, a processor configured to calculate power usage information using the digital signal, and a network interface module configured to transmit the power usage information to a server via the power line network.

The above and other preferred features, including various novel details of implementation and combination of elements will now be more particularly described with reference to the accompanying drawings and pointed out in the claims. It will be understood that the particular methods and apparatus are shown by way of illustration only and not as limitations. As will be understood by those skilled in the art, the principles and features explained herein may be employed in various and numerous embodiments.

### BRIEF DESCRIPTION OF THE DRAWINGS

The accompanying drawings, which are included as part of the present specification, illustrate the presently preferred embodiment of the present invention and together with the general description given above and the detailed description of the preferred embodiment given below serve to explain and teach the principles of the present invention.

FIG. 1 illustrates a simplified diagram for an exemplary power meter network, according to one embodiment;

FIG. 2 illustrates an exemplary power metering system, according to one embodiment;

FIG. 3A illustrates an exemplary power meter configured to measures both voltage and current, according to one embodiment;

FIG. 3B illustrates internal circuitry of an exemplary power meter, according to one embodiment;

FIG. 4A illustrates an exemplary power meter that is configured for measuring current, according to one embodiment;

FIG. 4B illustrates an exemplary internal circuit of a power meter, according to one embodiment; and

FIG. 5 illustrates an exemplary power meter with integrated wireless network interface, according to one embodiment.

It should be noted that the figures are not necessarily drawn to scale and that elements of similar structures or functions are generally represented by like reference numerals for illustrative purposes throughout the figures. It also should be noted that the figures are only intended to facilitate the description of the various embodiments described herein. The figures do not describe every aspect of the teachings described herein and do not limit the scope of the claims.

### DETAILED DESCRIPTION

A system and method for monitoring energy usage through a power line network is disclosed. According to an embodiment, the present system for monitoring power usage comprises a power line having one or more phases and metering device. The metering device comprises an A/D converter configured to receive an electrical signal and convert the electrical signal to a digital signal, a processor configured to calculate power usage information using the digital signal, and a network interface module configured to transmit the power usage information to a server via the power line network.

It is to be appreciated that various embodiments of the present invention provide numerous advantages over conventional systems. Among other things, power meter systems according to the present embodiments are easy and inexpensive to deploy compared to conventional systems. For example, power meter systems according to the present embodiments can be deployed to measure power usage of each of the appliances within a house hold without having to pieces through each of electrical power lines that connect to the appliances. In addition, the present power meter systems are connected to the network, thus giving users instant and convenient access to power usage information. There are other benefits as well.

Each of the features and teachings disclosed herein can be utilized separately or in conjunction with other features and teachings to provide a system and method for monitoring energy usage through a power line network. Representative examples utilizing many of these additional features and teachings, both separately and in combination, are described in further detail with reference to the attached drawings. This detailed description is merely intended to teach a person having ordinary skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings.

In the following description, for purposes of explanation only, specific nomenclature is set forth to provide a thorough understanding of the present invention. However, it will be apparent to one skilled in the art that these specific details are not required in order to practice the various inventive concepts disclosed herein.

Some portions of the detailed descriptions that follow are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Various apparatus can be used with the various embodiments described herein. One apparatus may be specially constructed for the required purposes, while another may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, and each coupled to a computer system bus.

The algorithms presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description below. It will be appreciated that a variety of programming languages may be used to implement the teachings of the invention as described herein.

Moreover, the various features of the representative examples and the dependent claims may be combined in ways that are not specifically and explicitly enumerated in order to provide additional useful embodiments of the present teachings. It is also expressly noted that all value ranges or indications of groups of entities disclose every possible intermediate value or intermediate entity for the purpose of original disclosure, as well as for the purpose of restricting the claimed subject matter. It is also expressly noted that the dimensions and the shapes of the components shown in the figures are designed to help to understand how the present teachings are practiced, but not intended to limit the dimensions and the shapes shown in the examples.

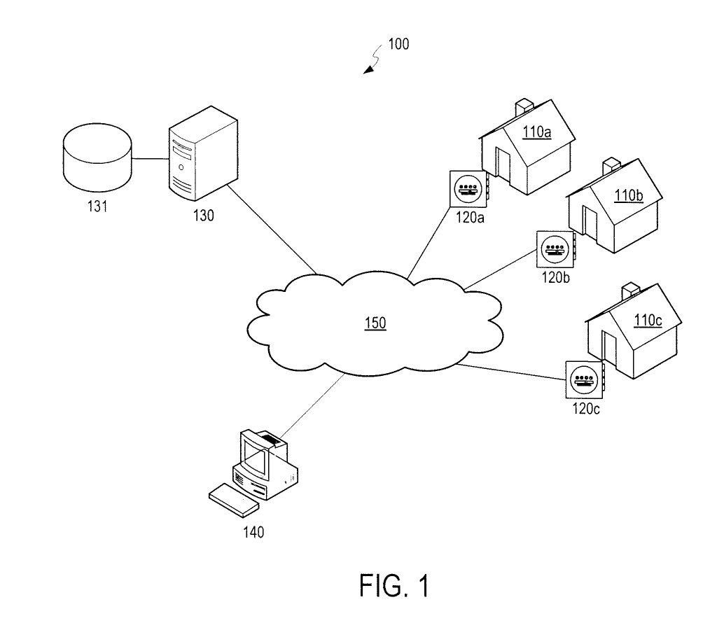

FIG. 1 illustrates a simplified diagram for an exemplary power meter network, according to one embodiment. Power meter network 100 is merely an example, which should not be understood to unduly limit the scope of the present subject matter. One of ordinary skill in the art would recognize many variations, alternatives, and modifications without deviating from the scope of the present subject matter. According to one embodiment, a plurality of households 100 is part of power meter network 100. Each of households 110 has a power meter 120 coupled to a main power line. Household 110 may represent a residence, a commercial or government building, a hospital, a hotel, or the like where power usage is monitored. Although only one power meter 120 is shown per household 110 in FIG. 1, power meter 120 may actually represent one or more power meters coupled together. For example, power meter 120a may collectively represent both a main power meter of household 110a that is coupled to the main electricity line and additional sub power meters that are coupled to various outlets and/or appliances in household 110a. The sub power meters are connected to the main power meter and other sub power meters to form power line network 110. According to one embodiment, one or more power meters of a particular household 110 are configured to share information such as power consumption and power usage over time.

According to one embodiment, a repeater boosts the network signal allowing it to travel further distances over the power line. A repeater can be a stand alone device or embedded in another device. The present subject matter may been applied in a local area network environment, where the range of power line communication network is extended through the use of repeaters, but it would be recognized that other applications exist. The present subject matter may also be applied to building area networking, home area networking, office networking, apartments, any combination thereof, and other networking applications.

According to one embodiment, a plurality of power meters 120 are connected to server 130 and database 131 over the network 150. Server 130 stores power usage data collected from the plurality of power meters 120 and user specific data in database 131. The stored data in database 131 may be made available to users in a variety of ways. Preferably, server 130 runs a web server and users connect to server 130 using a web browser from a network-enabled device over the Internet.

According to one embodiment, power meters 120 may be geographically scattered over a wide area but connected to the Internet. Server 130 collects power usage information from the networked power meters 120, and provides such information to a user who connects to server 130 over the network 150. User's console 140 may be located at any location provided that a network connection to network 150 is available. For example, user's console 140 may a personal computer in user's household 110 or a mobile phone.

According to one embodiment, power usage information is made available to users through network 150 to allow the users to monitor their power usage. Power meters 120 are connected to network 150, through which power usage information is transmitted to server 130 and stored in database 131. Users are able to access and view power usage information through network 150 using a console 140. Depending on the application, console 140 may be a personal computer, a cellular phone, a portable digital assistant, and other communication device that has a network connectivity to server 130. The user connects to server 130 using console 140 to see power usage associated with various power outlets of his/her household 110. The power usage information may be viewed to a user even when the user is not physically residing in the household where power is metered.

According to one embodiment, the power usage information provided by power meters 120 is processed by a power management system. The power management system may reside anywhere in network 150. Alternatively, the power management system may be distributed to each household 110. In the latter case, the power management system process the power usage information from power meter 120 including sub power meters from the household 110 and send the processed data to server 130. The data processing may occur in various steps in reference to various reference data. For example, the power usage over a period may be compared with that over the same period last year to monitor the power saving. If a sub power meter is installed to a power hog such as a washer or dryer, the power saving achieved with the sub power meter may be obtained before and after installing the sub power meter. Using the processed information, the power management system performs a variety of tasks and generates useful data to help users to reduce power consumption, procure less expensive source for energy, etc. According to one embodiment, server 130 runs a web server that provides power usage information to users through a web interface.

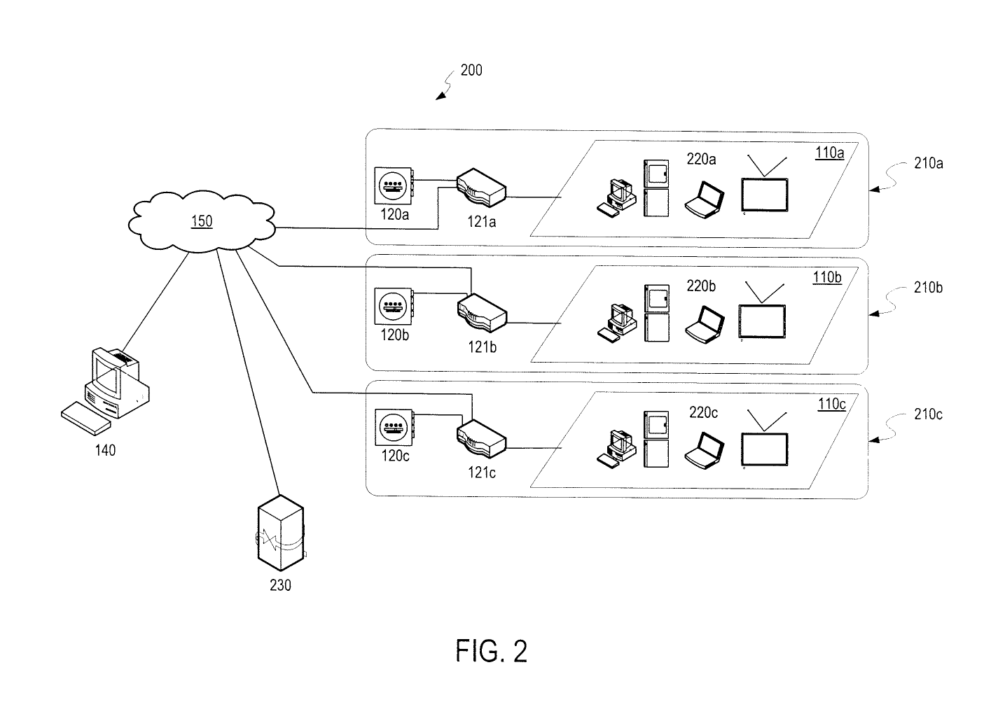

FIG. 2 illustrates an exemplary power metering system, according to one embodiment. Power metering system 200 is merely an example, which should not unduly limit the scope of the claims. One of ordinary skill in the art would recognize many variations, alternatives, and modifications. According to one embodiment, power meters 120 and appliances 220 form a power line communication (PLC) network 210. Appliances 220 such as a personal computer, a washer, a dryer, a dishwasher, a television, etc. may be connected to a PLC network 210 of a household 110 and ultimately to network 150 via a built-in PLC device or via a coupled power meter 120 that has a network connectivity. In the latter case, power meter 120 is a standalone PLC device with PLC network connectivity. PLC devices, whether they are power meters 120 or appliances 220, may have a data processing capability to convert, process raw input data as well as a network capability to generate and transmit data packets to the PLC network 210 and/or network 150.

According to one embodiment, various PLC devices and power meters 120 are connected to form a virtual local area network. The virtual network might be overlaid on an existing home network. Power meters 120 may be selectively connectable to a PLC device on the virtual local area network. Through the virtual local area network, the PLC device may access power usage information measured by the power meters 120. In one embodiment, power meter 120 may be configured to provide power usage information to network 150 via a PLC device. The network access is controlled by the virtual local area network, which determines the interconnection and security of the computing device connected to the network 150.

According to one embodiment, each power meter 120 transmits power usage information over a PLC network 210. The PLC network 210 may also serve as a network for other types of data transmission, such as Internet traffic, video, audio, etc. The PLC network 210 may exist as a virtual network over an existing home network or alternatively exist over a dedicated network platform. When transmitting power usage information, PLC network 210 may utilize the existing electrical wires (e.g., power lines, phone lines) spread throughout the household 110 as a data transmittal medium and transmit data signals to the electrical signals.

Through the PLC network 210, power meters 120 may also be connected to other power meters 120 such that power related information is shared. According to one embodiment, a main power meter 120 is coupled to a main power line for all the outlets in the household 110. The main power meter 120 may also includes a number of sub power meters. The sub power meters are connected to various outlets that derive their power from the main power line.

According to one embodiment, main power meter 120 measures both voltage and current information. In cases when other sub power meters are configured to measure only the current, the voltage information obtained from the main power meter 120 is used to determine the consumed power at those sub power meters as they share the same voltage. Depending on the application, power usage is generated in various units, such as average power consumption per hour, kilowatt-hour, etc.

According to one embodiment, the power management system verifies power consumption at a household 110 by comparing the total power consumption as determined the main power meter 120 and the sum of power consumptions measured by all the sub power meters. The two numbers must be essentially equal unless there are errors caused by power leakage, errors with the instruments, or others reasons that are not traceable.

According to one embodiment, power meters 120 may be connected to the network 150 via a PLC network 210 and/or through a broadband modem 121. According to one embodiment, power meter 120 is a standalone unit that is connected directly to network 150. A broadband modem 121 connects the PLC network 210 to network 150. Gateway 230 is also connected to the network 150 to operate as a hosted server and aggregate data from power meters 120. The aggregated data is processed and made available to device 140 that is connected to network 150 through a user interface, for example, a web page.

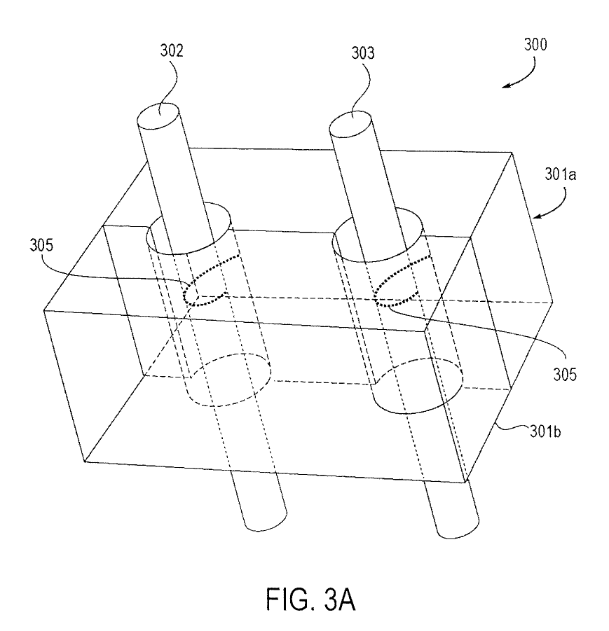

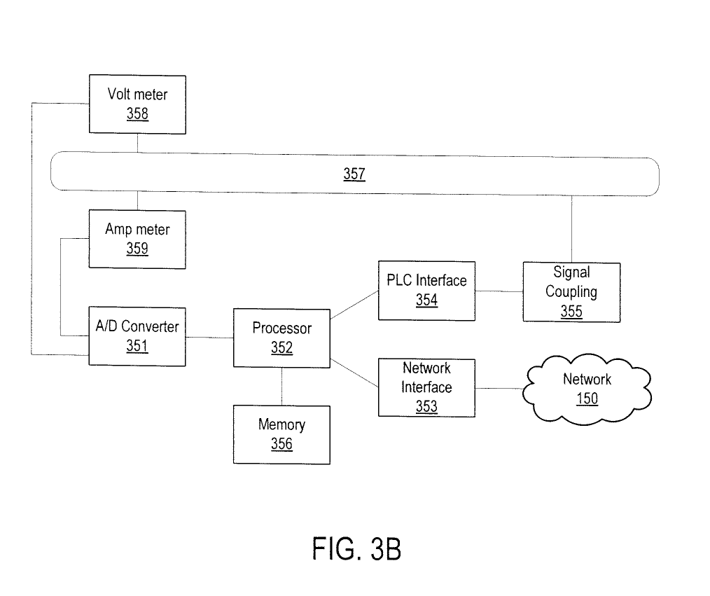

FIG. 3A illustrates an exemplary power meter configured to measure both voltage and current, according to one embodiment. Housing 301 of power meter 300 may be made of various types of insulating materials and/or dielectric materials, such as glass, plastics, ceramic, rubber, etc. Housing 301 may also be made of an UL approved fire retardant material to avoid or reduce fire hazard. Various insulated electrical circuitry (not shown in FIG. 3) is integrated into housing 301 to measure and transmit power usage information. Housing 301 provides electrical shields for various circuits enclosed therein and/or electrical wires 302 and 303 from interference (e.g., electromagnetic interference).

According to one embodiment, housing 301 measures both voltage and current by clamping electrical wires 302 and 303. Housing 301 has two openings to accommodate two electrical wires 303 and 302. In one embodiment, housing 301 is made of two pieces 301a and 301b that are clamped together for easy installation over electrical wires 302 and 303. According to one embodiment, voltage is measured through electrical probes 305 that pierce into electrical wires 302 and 303. Current may be measured without physical contact between housing 301 and electrical wires 302 and 303. For example, eddy current generated by the electromagnetic field of the current flowing through electrical wires 302 and 303 measures the current flowing through electrical wires 302 and 303.

Power meter 300 is configured to determine power usage based on the current and voltage reading. For example, power meter 300 includes an analog-to-digital (A/D) converter that converts analog reading of the voltage and current into a digital representation. Power 300 may also include a processor to compute the amount of consumed energy over time based on the current and voltage reading at different points in time.

According to one embodiment, power meter 300 includes PLC circuitry to transmit the information related to power usage to other power meters and/or devices. Alternatively, power meter 300 may be attached to a PLC device. In this case, the measured voltage and current data is fed to the PLC device. In either case, power meter 300 is connected to network 150 through a PLC network 210 and is configured to upload power usage information to one or more computers (e.g., server 130) over network 150.

FIG. 3B illustrates internal circuitry of an exemplary power meter, according to one embodiment. Analog-to-digital (A/D) converter 351 is connected to volt meter 358 and amp meter 359. Volt meter 358 obtains voltage reading from electrical probes 305 that is connected to power line 357. Amp meter 359 determines the amount of current flows through power line 357. The current reading for the power line 357 may be determined by eddy current generated by the electromagnetic field of the current flowing through the power line 357. The analog readings from both voltage meter 358 and amp meter 359 are converted to digital values by A/D converter 351. Depending on the degree of accuracy needed, A/D converter 351 converts analog readings at the desirable resolution and precision. The resolution and precision of the A/D conversion may be configured using a hardware setting (e.g., dip switch on power meter) by a user or a technician. For example, higher resolution and faster sampling may be required during calibration to accurately measure the power consumption of a known electrical node. In a normal operating condition, the resolution and sampling rate might be adjusted to obtain relatively accurate readings without sacrificing the accuracy of obtained data.

Processor 352 receives voltage and current reading in a digital format from the A/D converter 352. Processor 352 calculates power usage information based on the voltage and current readings. For example, processor 352 determines power usage based on the average current and voltage reading over a predetermined period of time. Processor 352 may periodically store voltage and current readings into memory 356. Processor 352 refers to the stored voltage and current readings from memory 356 to calculate the new power usage information. After the calculation, the processor 352 stores the updated power usage information to memory 356.

According to one embodiment, processor 352 is connected to network interface 353 to transmit power usage information over network 150. The power usage information includes the voltage reading, current reading as well as the time the information associated with the voltage and/or current reading. Power usage information is inserted into a data packet that is compliant with network 150.

According to one embodiment, power usage information is transmitted through the power line. The power usage information is converted into a format that is compatible with PLC network 210. In one embodiment, orthogonal frequency domain multiplexing (OFDM) modulation is used for data transmission. In this case, PLC interface module 354 receives data packets from network interface 353, converts the data packets into the OFDM data format, and sends the converted data signal in OFDM format to signal coupling module 355. Signal coupling module 355 couples the OFDM format data signal to power line 357. Signal coupling module 355 may be configured to couple OFDM format signal to different phases of the power transmission.

It is appreciated that some components described above are capable of both transmitting and receiving information. For example, signal coupling module 355 not only transmits OFDM data packets to power line 357 but also is capable of receiving data signal from power line 357. The PLC interface module 354 is able to convert the receive data signal, which may be in OFDM format, back to data packet that is readable by processor 352. Processor 352 may also be configured to process received data packets. Depending on the application, exchanged data may be system control information, firmware update, or power usage information.

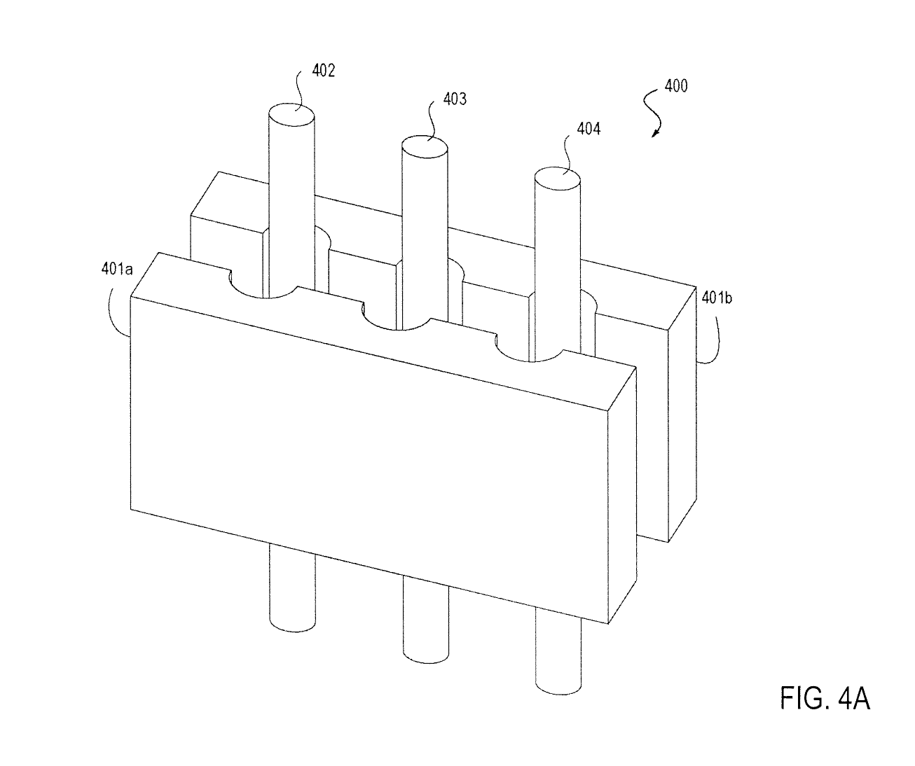

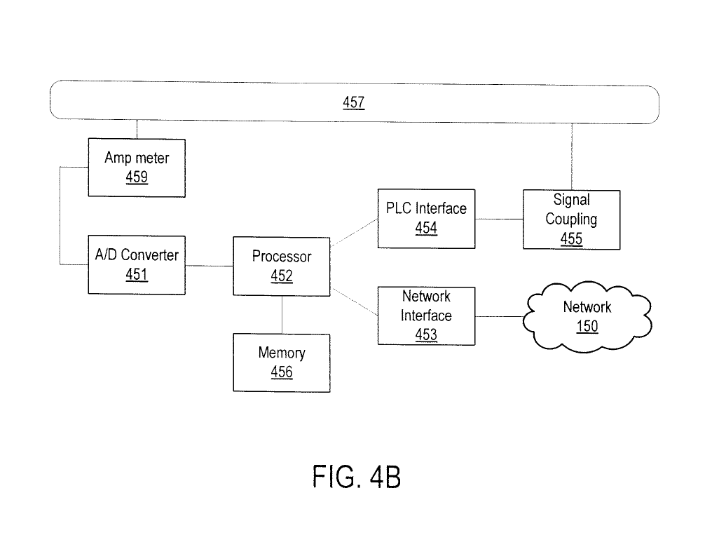

FIG. 4A illustrates an exemplary power meter that is configured for measuring current, according to one embodiment. For example, power meter 400 is a sub power meter that is connected to a main power meter 300. As described above, power meter 300 is configured to measure both voltage and current from a main power line. Power meter 400 is configured to measure only current, but the power usage is calculated along with the voltage measured from the main power line. In this configuration, power meter 400 provides a mechanism to compensate for the phase shift of the AC voltage signal at the power outlet in comparison to the main power line, such that accurate power usage data is calculated. According to one embodiment, power meter 400 has two housing members 401a and 401b with three openings. Housing members 401a and/or 401b may encase various electrical circuitry to perform power measurement and network communication. Housing members 401a and 401b may be manufactured using a variety of insulating and/or dielectric materials, such as plastics, glass, ceramic, etc. Housing members 401a and 401b are secured together by disengageably coupling them with coupling members (not shown). The two-piece housing design of power meter 400 affords easy installation. Although two-piece design of power meter 400 is shown for illustration purpose, it is appreciated that one-piece or multi-piece designs are also possible without deviating the scope of the present subject matter.

In contrast to power meter 300, power meter 400 is configured to measure only current. Therefore, power meter 400 does not need electrical probes that pierce into electrical wires to obtain voltage measurement. Instead, power meter 400 receive voltage information from power meter 300 or any other PLC device that has voltage information through network interface 453. Since no piercing is needed for power meter 400 for voltage measurement, the deployment cost for power meter 400 is lower compared to power meter 300 that requires wire piercing for voltage measurement. Because no piercing is required, professional installation might not be required to install sub power meter 400.

FIG. 4B illustrates an exemplary internal circuit of a power meter, according to one embodiment. Power meter 400 has A/D converter 451, processor 452, memory 456, network interface 453, PLC interface 454, analog front end 455, and amp meter 459. Analog-to-digital (A/D) converter 451 is connected to amp meter 459. In contrast to power meter 300, power meter 400 does not have a voltage meter because power meter 400 obtains voltage information from other source on the PLC network 210. Amp meter 459 determines the amount of current flows through power line 457. For example, the current reading for power line 457 is determined by the amount of eddy current generated by the electromagnetic field of the current flowing through power line 457. A/D converter 451 converts analog readings from amp meter 459 to digital values. Depending on the degree of accuracy needed, A/D converter 451 converts analog readings at the desirable resolution and precision.

Processor 452 is configured to receive current readings in a digital format from A/D converter 451. Processor 452 is also connected to memory 456. Processor 452 calculates power usage information based on the current reading from amp meter 459 and voltage information obtained from other source on the PLC network 210. For example, voltage information is made available in real time by a separate power meter that is connected to the main power line. According to one embodiment, processor 452 determines power usage based on the average current and voltage information over a predetermined period of time. Processor 452 periodically stores voltage and current information into memory 456. Processor 452 refers to the stored voltage and current readings from memory 456 to calculate the new power usage information. After the calculation, the processor 452 stores the updated power usage information to memory 456.

According to one embodiment, processor 452 is connected to network interface 453 to transmit power usage information and to receive voltage information over network 150. The power usage information includes the voltage reading, current reading as well as the time the information associated with the voltage and/or current reading. Power usage information is inserted into a data packet that is compliant with network 150.

According to one embodiment, power usage information is transmitted through the power line. The power usage information is converted into a format that is compatible with PLC network 210. In one embodiment, orthogonal frequency domain multiplexing (OFDM) modulation is used for data transmission. In this case, PLC interface module 354 receives data packets from network interface 453, converts the data packets into the OFDM data format, and sends the converted data signal in OFDM format to signal coupling module 455. Signal coupling module 455 couples the OFDM format data signal to power line 457. Signal coupling module 455 may be configured to couple OFDM format signal to different phases of the power transmission.

It is appreciated that some components described above are capable of both transmitting and receiving information. For example, signal coupling module 455 not only transmits OFDM data packets to power line 457 but also is capable of receiving data signal from power line 457. The PLC interface module 454 is able to convert the receive data signal, which may be in OFDM format, back to data packet that is readable by processor 452. Processor 452 may also be configured to process received data packets. Depending on the application, exchanged data may be system control information, firmware update, or power usage information.

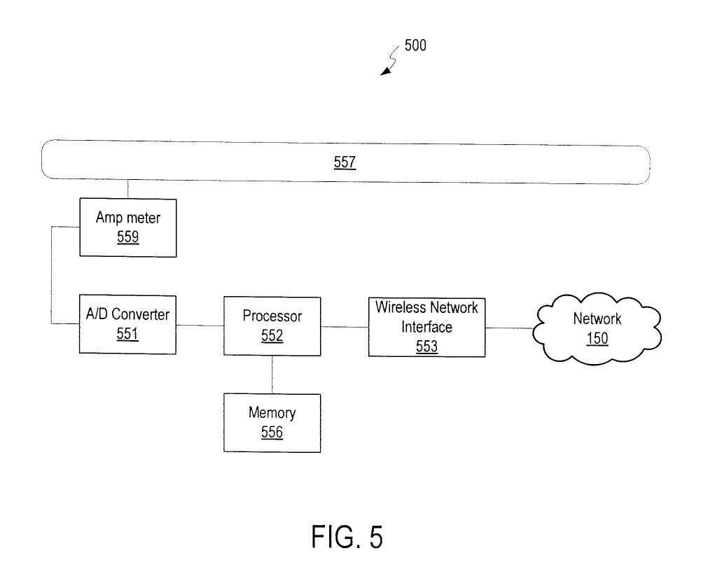

FIG. 5 illustrates an exemplary power meter with integrated wireless network interface, according to one embodiment. Power meter 500 may replace power meter 300 of or power meter 400 when a wired PLC network is not deployed or inadequate for deployment. In this case, power meter 500 is connected to other wireless PLC device to exchange power usage data. For example, power meter 500 is a sub power meter and communicates with a main power meter 120 wirelessly.

Analog-to-digital (A/D) converter 551 is connected to amp meter 559. Amp meter 559 measure current flowing through power line 557 as amp meter 359 or 459 measures current through power line 357 or 457. Similarly, processor 552 or memory 556 operates the same functions as processor 352 or 452, and memory 356 or 456.

According to one embodiment, power meter 500 is wirelessly connected to PLC network 210 to transmit information related to power usage, and to receive voltage information. The wireless communication may employ a different communication protocol from what the wired PLC network is based on. Therefore, the data packets through wireless network interface 553 may be packetized to comply with the wireless network format.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

We claim:

1. A system comprising:
a power line having one or more phases; and
a metering device comprising:
an A/D converter configured to receive an electrical signal and convert the electrical signal to a digital signal;
a processor configured to calculate power usage information using the digital signal; and
a network interface module configured to transmit the power usage information to a server via the power line network.

2. The system of claim 1, wherein the electrical signal comprises an electrical current signal generated by an amp meter.

3. The system of claim 2, wherein the electrical signal further comprises an electrical voltage signal generated by a volt meter.

4. The system of claim 3, wherein the metering device pierces through the power line to measure the electrical voltage signal.

5. The system of claim 1, wherein the metering device further comprises:
a power line communication (PLC) interface module configured to convert the digital signal into a transport signal in a transport format, the transport format being compatible with the power line network; and
a signal coupling module configured to couple the transport signal into each phase of the one or more phases to generate a coupled signal, wherein the coupled signal is transmitted to the power line.

6. The system of claim 1 further comprises a gateway configured to receive the coupled signal and communicate with the server.

7. The system of claim 1, wherein the server runs a web server providing the power usage information to a user via a user interface.

8. The system of claim 5, wherein the transport format is an orthogonal frequency domain multiplexing (OFDM) format.

9. The system of claim 1, wherein the metering device comprises a mechanical housing comprising a first housing member and a second housing member,
wherein the first and second housing members are disengageably coupled by a connecting member and the second connecting member, and
wherein the first and second housing members have an opening shaped to accommodate the power line.

10. The system of claim 9, wherein the mechanical housing is made of an insulating material.

11. The system of claim 9, wherein the mechanical housing is made of a fire retardant material.

12. The system of claim 1 further comprising an appliance module configured to isolate power consumption associated with the metering device.

13. The system of claim 1 further comprising a wireless module configured to wirelessly transport the power usage information to the server.

14. A power metering apparatus comprising:
an A/D converter configured to receive an electrical signal from a power line and convert the electrical signal to a digital signal, wherein the power line has one or more phases;
a processor configured to calculate power usage information using the digital signal;
a network interface module configured to transmit the power usage information to a server via the power line network.

15. The power metering apparatus of claim 14, wherein the electrical signal comprises an electrical current signal generated by an amp meter.

16. The power metering apparatus of claim 15, wherein the electrical signal further comprises an electrical voltage signal generated by a volt meter.

17. The power metering apparatus of claim 16 pierces through the power line to measure the electrical voltage signal.

18. The power metering apparatus of claim 14 further comprising:
a power line communication (PLC) interface module configured to convert the digital signal into a transport signal in a transport format, the transport format being compatible with the power line network; and
a signal coupling module configured to couple the transport signal into each phase of the one or more phases to generate a coupled signal, wherein the coupled signal is transmitted to the power line.

19. The power metering apparatus of claim 14, wherein the power usage information is transmitted to the server via a gateway.

20. The power metering apparatus of claim 14, wherein the server runs a web server providing the power usage information to a user via a user interface.

21. The power metering apparatus of claim 18, wherein the transport format is an orthogonal frequency domain multiplexing (OFDM) format.

22. The power metering apparatus of claim 14 further comprising a mechanical housing comprising a first housing member and a second housing member,
wherein the first and second housing members are disengageably coupled by a connecting member and the second connecting member, and
wherein the first and second housing members have an opening shaped to accommodate the power line.

23. The power metering apparatus of claim 22, wherein the mechanical housing is made of an insulating material.

24. The power metering apparatus of claim 22, wherein the mechanical housing is made of a fire retardant material.

25. The power metering apparatus of claim 14 is connected to an appliance module configured to isolate power consumption associated with the power metering apparatus.

26. The power metering apparatus of claim 14 further comprising a wireless module configured to wirelessly transport the power usage information to the server.

27. A method for monitoring power usage through a power line network, the method comprising:
converting an electrical signal received from a power line a digital signal, wherein the power line has one or more phases;
calculating power usage information using the digital signal;
transmitting the power usage information to a server via the power line network.

28. The method of claim 27 further comprising measuring an electrical current signal generated by an amp meter.

29. The method of claim 28 further comprising measuring an electrical voltage signal generated by a volt meter.

30. The method of claim 29 further comprising piercing through the power line to measure the electrical voltage signal.

31. The method of claim 27 further comprising:
converting the digital signal into a transport signal in a transport format, the transport format being compatible with the power line network;
coupling the transport signal into each phase of the one or more phases;
generating a coupled signal; and
transmitting the coupled signal to the power line.

32. The method of claim 27, wherein the power usage information is transmitted to the server via a gateway.

33. The method of claim 27, wherein the server runs a web server providing the power usage information to a user via a user interface.

34. The method of claim 31, wherein the transport format is an orthogonal frequency domain multiplexing (OFDM) format.

35. The method of claim 27, wherein the electrical signal is measured using a metering device comprising a mechanical housing, the mechanical housing comprising a first housing member and a second housing member,
wherein the first and second housing members are disengageably coupled by a connecting member and the second connecting member, and
wherein the first and second housing members have an opening shaped to accommodate the power line.

36. The method of claim 35, wherein the mechanical housing is made of an insulating material.

37. The method of claim 35, wherein the mechanical housing is made of a fire retardant material.

38. The method of claim 27 further comprising isolating power consumption connected to an appliance.

39. The method of claim 27 further comprising wirelessly transporting the power usage information to the server.
